(19) United States
(12) Patent Application Publication
(10) Pub. No.: US 2025/0372903 A1
(43) Pub. Date: Dec. 4, 2025

(54) PLUGGABLE MODULE HAVING AN ACTIVE DEVICE

(71) Applicant: TE Connectivity Solutions GmbH, Schaffhausen (CH)

(72) Inventor: Brian Patrick Costello, Fremont, CA (US)

(21) Appl. No.: 18/679,635

(22) Filed: May 31, 2024

(51) Int. Cl. H01R 12/78; G02B 6/42; H01R 12/71

(52) U.S. Cl. CPC H01R 12/78; G02B 6/4261; G02B 6/4281; H01R 12/716

(57) ABSTRACT

A circuit board assembly for a pluggable module includes upper and lower interface printed circuit boards that includes first and second data channels, respectively. The interface printed circuit boards includes mating pads at corresponding mating edges thereof forming portions of the data channels and configured to be plugged into corresponding card edge connectors. The circuit board assembly includes a main printed circuit board that includes an active device electrically connected to the first and second data channels restoring signals transmitting along the data channels. The circuit board assembly includes upper and lower flexible circuits connected between the interface printed circuit boards and the main printed circuit board.

### BACKGROUND OF THE INVENTION

The subject matter herein relates generally to electrical connector assemblies.

Some communication systems utilize communication connectors, such as electrical connector assemblies to interconnect various components of the system for data communication. Some known communication systems use pluggable modules, such as I/O modules or circuit cards, which are electrically connected to the electrical connector assemblies. The pluggable modules have module circuit cards having card edges that are mated with the electrical connector assemblies during the mating operation. There is a need for connectors and circuit boards of communication systems to have greater contact density and/or data throughput. Some known pluggable modules incorporate dual paddle cards to increase the number of signal channels provided through the pluggable module. Some systems utilize active devices, such as re-drivers or re-timers at the component interfaces to extend cable reach and enable smaller cable diameters. However, incorporation of active devices in dual paddle card is problematic. Removal of heat generated by the active devices is difficult. Positioning of active components in dual paddle card pluggable modules is difficult.

A need remains for an improved pluggable module for a communication system having an active device to restore signals transmitted along the data channels.

### BRIEF DESCRIPTION OF THE INVENTION

In one embodiment, a circuit board assembly for a pluggable module is provided and includes an upper interface printed circuit board that includes first data channels. The upper interface printed circuit board includes an upper mating edge and upper mating pads proximate to the upper mating edge forming portions of the first data channels. The upper mating edge is configured to be plugged into a first card edge connector to mate the upper mating pads with first contacts of the first card edge connector. The circuit board assembly includes a lower interface printed circuit board that includes second data channels. The lower interface printed circuit board includes a lower mating edge and lower mating pads proximate to the lower mating edge forming portions of the second data channels. The lower mating edge is configured to be plugged into a second card edge connector to mate the lower mating pads with second contacts of the second card edge connector. The circuit board assembly includes a main printed circuit board that includes an active device configured to be electrically connected to the first data channels and the second data channels. The active device includes a repeater device restoring signals transmitting along the first data channels and/or the second data channels. The circuit board assembly includes an upper flexible circuit connected between the upper interface printed circuit board and the main printed circuit board to electrically connect the first data channels to the active device. The circuit board assembly includes a lower flexible circuit connected between the lower interface printed circuit board and the main printed circuit board to electrically connect the second data channels to the active device.

In another embodiment, a pluggable module is provided and includes a shell having a cavity. The shell has a mating end. The shell has an opening at the mating end. The pluggable module includes a circuit board assembly received in the cavity of the shell. The circuit board assembly includes an upper interface printed circuit board, a lower interface printed circuit board, a main printed circuit board, an upper flexible circuit connected between the upper interface printed circuit board and the main printed circuit board, and a lower flexible circuit connected between the lower interface printed circuit board and the main printed circuit board. The upper interface printed circuit board includes first data channels. The upper flexible circuit electrically connects the first data channels to the active device. The upper interface printed circuit board includes an upper mating edge and upper mating pads proximate to the upper mating edge forming portions of the first data channels. The upper mating edge is presented at the mating end of the shell for plugging into a first card edge connector to mate the upper mating pads with first contacts of the first card edge connector. The lower interface printed circuit board includes second data channels. The lower flexible circuit electrically connects the second data channels to the active device. The lower interface printed circuit board includes a lower mating edge and lower mating pads proximate to the lower mating edge forming portions of the second data channels. The lower mating edge is presented at the mating end of the shell for plugging into a second card edge connector to mate the lower mating pads with second contacts of the second card edge connector. The main printed circuit board includes an active device electrically connected to the first data channels and the second data channels. The active device includes a repeater device restoring signals transmitting along the first data channels and the second data channels.

In a further embodiment, a pluggable module is provided and includes a shell having a cavity. The shell has a mating end and a cable end. The shell has an opening at the mating end. The pluggable module includes a cable assembly extending from the cable end. The cable assembly cables have conductors. The pluggable module includes a circuit board assembly received in the cavity of the shell and terminated to the conductors of the cables of the cable assembly. The circuit board assembly includes an upper interface printed circuit board, a lower interface printed circuit board, a main printed circuit board, an upper flexible circuit connected between the upper interface printed circuit board and the main printed circuit board, and a lower flexible circuit connected between the lower interface printed circuit board and the main printed circuit board. The upper interface printed circuit board includes first data channels. The upper flexible circuit electrically connects the first data channels to the active device. The upper interface printed circuit board includes an upper mating edge and upper mating pads proximate to the upper mating edge forming portions of the first data channels. The upper mating edge is presented at the mating end of the shell for plugging into a first card edge connector to mate the upper mating pads with first contacts of the first card edge connector. The lower interface printed circuit board includes second data channels. The lower flexible circuit electrically connects the second data channels to the active device. The lower interface printed circuit board includes a lower mating edge and lower mating pads proximate to the lower mating edge forming portions of the second data channels. The lower mating edge is presented at the mating end of the shell for plugging into a second card edge connector to mate the lower mating pads with second contacts of the second card edge connector. The main printed circuit board includes an active device that is configured to be electrically connected to the first data channels and the second data channels and is configured to be electrically connected to the conductors of the cables of the cable assembly. The active device includes a repeater device restoring signals transmitting along the first data channels and the second data channels.

### BRIEF DESCRIPTION OF THE DRAWINGS

FIG. 1 is a front perspective view of a communication system formed in accordance with an exemplary embodiment.

FIG. 2 is a front perspective view of the electrical connector assembly in accordance with an exemplary embodiment.

FIG. 3 is a front perspective view of the pluggable module in accordance with an exemplary embodiment.

FIG. 4 is a front perspective view of the circuit board assembly in accordance with an exemplary embodiment showing the cable assembly terminated to the circuit board assembly.

FIG. 5 is a rear perspective view of the circuit board assembly in accordance with an exemplary embodiment.

FIG. 6 is a side view of the circuit board assembly in accordance with an exemplary embodiment showing the cable assembly terminated to the circuit board assembly.

FIG. 7 is an exploded view of the pluggable module in accordance with an exemplary embodiment.

FIG. 8 is a front perspective view of the circuit board assembly in accordance with an exemplary embodiment showing the cable assembly as a fiber optic cable assembly.

### DETAILED DESCRIPTION OF THE INVENTION

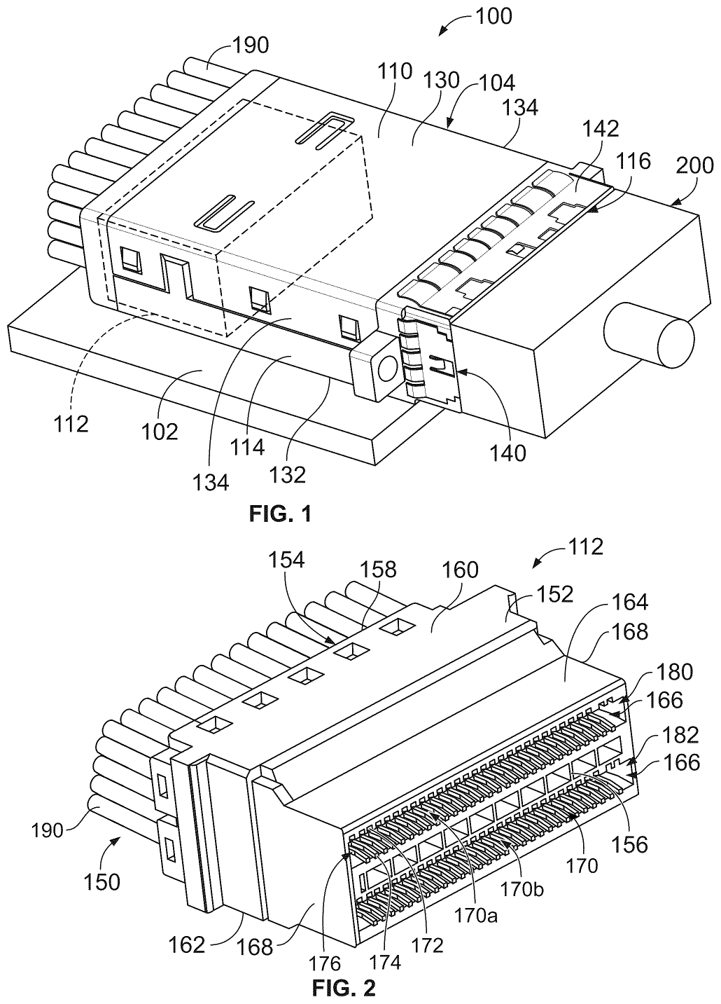

FIG. 1 is a front perspective view of a communication system 100 formed in accordance with an exemplary embodiment. The communication system 100 includes a device 102 and a receptacle connector assembly 104 mounted to the device 102. The communication system 100 includes a mating component, such as a pluggable module 200, configured to be mated with the receptacle connector assembly 104. For example, the pluggable module 200 may be plugged into a receptacle or cavity of the receptacle connector assembly 104.

The device 102 may be a circuit board in various embodiments. The device 102 may be a housing, chassis, panel, or other type of device in other various embodiments, such as arranged at the front of the connector assembly. For example, the device 102 may be a vertical wall (not shown) such as a panel or chassis with an opening or cutout that receives a portion of the receptacle connector assembly 104. The receptacle connector assembly 104 may be coupled to the device 102 using mounting lugs or brackets. The device may be oriented horizontally, vertically, or at another orientation.

The pluggable module 200 is configured to be electrically connected to the receptacle connector assembly 104. The pluggable module 200 may be an I/O module or a transceiver module. The pluggable module 200 may be electrically connected to the device 102. The pluggable module 200 may be connected to other components within the communication system 100, such as an integrated circuit component, a chip, a microprocessor, a memory module, or another component of the communication system, through cable connectors. The other components may be mounted to the device 102, such as remote from the receptacle connector assembly 104.

In an exemplary embodiment, the receptacle connector assembly 104 includes a receptacle cage 110 and an electrical connector assembly 112 (shown in phantom) adjacent the receptacle cage 110. For example, in the illustrated embodiment, the electrical connector assembly 112 is received in the receptacle cage 110. In other various embodiments, the electrical connector assembly 112 may be located rearward of the receptacle cage 110. In various embodiments, the electrical connector assembly 112 is a card edge connector and may be referred to hereinafter as a card edge connector 112. The card edge connector 112 may include one or more card slots for receiving paddle cards or other card edges of the pluggable module. In an exemplary embodiment, the card edge connector 112 may be a dual slot card edge connector having a pair of card slots configured to receive corresponding card edges. In other various embodiments, multiple card edge connectors 112 may be provided, such as being stacked, to form stacked card slots. In various embodiments, the card edge connector 112 is provided at end(s) of cables(s) 190. The electrical connector assembly 112 may be electrically connected to the device 102. The electrical connector assembly 112 may be connected to other components by cables of a cable connector.

In various embodiments, the receptacle cage 110 is enclosed and provides electrical shielding for the electrical connector assembly 112. The pluggable module 200 is loaded into the receptacle cage 110 and is at least partially surrounded by the receptacle cage 110. The receptacle cage 110 includes a plurality of walls 114 that define one or more module channels 116 for receipt of corresponding pluggable module(s) 200. The walls 114 may be walls defined by solid sheets, perforated walls to allow airflow therethrough, walls with cutouts, such as for a heatsink or heat spreader to pass therethrough, or walls defined by rails or beams with relatively large openings, such as for airflow therethrough.

In the illustrated embodiment, the receptacle cage 110 is a single port cage having a single module channel 116. In alternative embodiments, the receptacle cage 110 constitutes a multi-port cage having multiple module channels 116. The module channels 116 may be arranged in a single row or may be stacked in multiple rows. In various embodiments, the receptacle cage 110 may include four module channels 116 arranged in a single row (for example, 1×4). However, the receptacle cage 110 may include multiple rows in alternative embodiments (for example, 2×2, 3×2, 4×2, 4×3, etc.). Any number of module channels 116 may be provided in various embodiments. Optionally, multiple electrical connector assemblies 112 may be arranged within the receptacle cage 110 for mating with the corresponding pluggable module 200.

In an exemplary embodiment, the walls 114 of the receptacle cage 110 include a top wall 130, a bottom wall 132, and side walls 134 extending between the top wall 130 and the bottom wall 132. The bottom wall 132 may rest on the device 102. In other various embodiments, the receptacle cage 110 may be provided without the bottom wall 132. Optionally, the module channel 116 may be open at the front and the rear. However, the walls 114 of the receptacle cage 110 may include a rear wall and/or a front wall.

The walls 114 define a cavity 140, which defines one or more of the module channels 116. For example, the cavity 140 may be defined by the top wall 130, the bottom wall 132, and the side walls 134. In an exemplary embodiment, other walls 114 may separate or divide the cavity 140 into the various module channels 116. For example, the walls 114 may include divider walls between the module channels 116.

In an exemplary embodiment, the receptacle cage 110 may include one or more gaskets 142 at the front and/or the rear for providing electrical shielding for the ports to the module channels 116. For example, the gaskets 142 may be configured to electrically connect with the pluggable module 200 and/or the opening in the device 102 where the receptacle cage 110 is mounted. The gaskets 142 may be configured to electrically connect to a panel or bezel.

In an exemplary embodiment, the receptacle connector assembly 104 may include one or more heat sinks (not shown) for dissipating heat from the pluggable module 200. For example, the heat sinks may be coupled to the top wall 130 for engaging the pluggable module 200 received in the module channels 116. The heat sinks may extend through openings in the top wall 130 to directly engage the pluggable module 200. Other types of heat sinks may be provided in alternative embodiments.

In an exemplary embodiment, each electrical connector assembly 112 is received in the cavity 140, such as at the rear. The electrical connector assembly 112 may be removable from the receptacle cage 110. In an exemplary embodiment, the pluggable module 200 are loaded through the front to mate with the electrical connector assembly 112. The shielding walls 114 of the receptacle cage 110 provide electrical shielding around the electrical connector assembly 112 and the pluggable module 200, such as around the mating interfaces between the electrical connector assembly 112 and the pluggable module 200.

FIG. 2 is a front perspective view of the electrical connector assembly 112 in accordance with an exemplary embodiment. The electrical connector assembly 112 includes one or more cable assemblies 150 and a housing 152 holding the cable assemblies 150. Each cable assembly 150 includes one or more contact assemblies 170 and cables 190 terminated to the corresponding contact assembly 170.

The housing 152 includes a cavity 154 that receives the cable assemblies 150. The housing 152 extends between a front 156 and a rear 158. The cavity 154 is open at the rear 158 to receive the cable assemblies 150. The housing 152 extends between a top 160 and a bottom 162. The housing 152 extends between opposite sides 168. The housing 152 may be generally box shaped in various embodiments. In the illustrated embodiment, the bottom 162 may define a mounting end configured to be mounted to the device 102 (shown in FIG. 1) and/or the receptacle cage 110. The sides 168 may define mounting ends configured to be mounted to the receptacle cage 110 and/or the device 102. The front 156 defines a mating end configured to be mated with the pluggable module 200 (shown in FIG. 1). Other orientations are possible in alternative embodiments.

The housing 152 includes a top wall at the top 160 and a bottom wall at the bottom 162. In the illustrated embodiment, the housing 152 includes a shroud 164 at the front 156 configured to be mated with the pluggable module 200. The shroud 164 is a nose cone configured to be plugged into the mating end of the pluggable module 200. The shroud 164 includes one or more housing card slots 166 open at the front. In the illustrated embodiment, the shroud 164 includes a pair of the card slots 166, such as an upper card slot and a lower card slot. However, in alternative embodiments, the shroud 164 may include greater or fewer card slots 166, such as a single card slot 166. In other various embodiments, the housing 152 may include multiple shrouds 164, which may be plugged into different pluggable modules (for example, an upper module and a lower module). In an exemplary embodiment, the contact assembly 170 is loaded in the cavity 154 and received in the shroud 164 for mating with the pluggable module 200.

In an exemplary embodiment, each cable assembly 150 includes a pair of the contact assemblies 170, such as an upper contact assembly 170a and a lower contact assembly 170b. The upper contact assembly 170a includes upper contacts 172 and the lower contact assembly 170b includes lower contacts 174 arranged in rows facing each other across a gap 176 configured to receive the mating component (for example, the card edge of the corresponding circuit card of the pluggable module 200). The upper and lower contact assemblies 170a, 170b may be similar or identical contact assemblies (for example, similarly or identically manufactured and/or assembled). The upper and lower contact assemblies 170a, 170b may be inverted relative to each other to form an upper mating interface for mating to the upper surface of the circuit card and a lower mating interface for mating to the lower surface of the circuit card.

In an exemplary embodiment, the electrical connector assembly 112 includes a first card edge connector 180 and a second card edge connector 182. The first card edge connector 180 is defined by the upper card slot 166 of the housing 152 and the upper contact assembly 170a. The first card edge connector 180 forms a first interface for mating with a first or upper circuit card. The second card edge connector 182 is defined by the lower card slot 166 of the housing 152 and the lower contact assembly 170b. The second card edge connector 182 forms a second interface for mating with a second or lower circuit card.

The cables 190 are terminated to the corresponding contacts of the contact assemblies 170. The cables 190 may be arranged in multiple rows. In an exemplary embodiment, the cables 190 are twin-axial cables each having a pair of signal conductors arranged in the core of the cable 190. The cables 190 may be shielded cables having cable shields surrounding the pairs of signal conductors. The cables 190 may include drain wires. Other types of cables may be used in alternative embodiments, such as coaxial cables, flat flexible cables, flexible circuits, twisted pair cables, and the like. In an exemplary embodiment, the cables 190 define high speed signal cables configured to transmit high speed data signals, such as 10 Gbps, 25 Gbps, 40 Gbps, 64 Gbps, 100 Gbps, or higher.

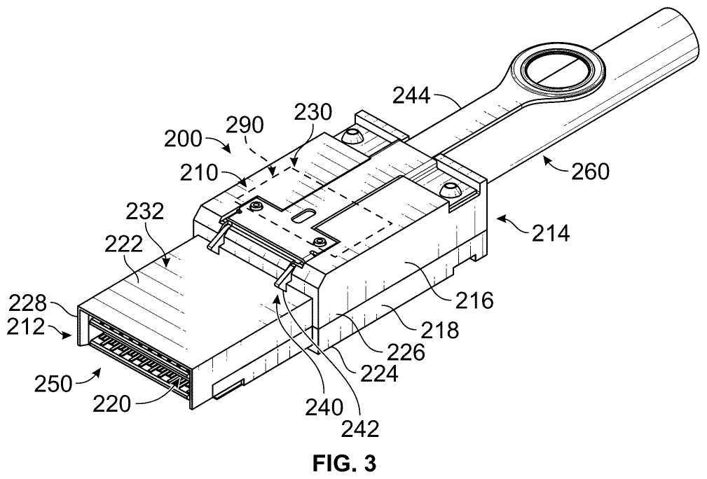

FIG. 3 is a front perspective view of the pluggable module 200 in accordance with an exemplary embodiment. The pluggable module 200 includes a shell 210 holding a circuit board assembly 250. A cable assembly 260 is electrically connected to the circuit board assembly 250. The circuit board assembly 250 is configured to be mated with the electrical connector assembly 112 (shown in FIG. 2). In an exemplary embodiment, the circuit board assembly 250 is a dual paddle card assembly having a pair of stacked circuit cards or paddle cards configured to be mated with the electrical connector assembly 112. In an exemplary embodiment, the circuit board assembly 250 includes an active module 290 that provides active signaling for the signals or data channels passing through the pluggable module 200. The active module 290 restores or enhances the signals transmitted along the data channels to improve signal conditioning or signal integrity along the data channels to improve communication through the communication system 100.

The shell 210 extends between a mating end 212 and a cable end 214. The mating end 212 is configured to be mated with the electrical connector assembly 112. The cable assembly 260 extends from the cable end 214. In the illustrated embodiment, the cable end 214 is opposite the mating end 212. For example, the mating end 212 may be located at a front of the shell 210 and the cable end 214 may be located at a rear of the shell 210. Other orientations are possible in alternative embodiments. For example, the pluggable module 200 may be a right-angle module having the cable end 214 perpendicular to the mating end 212.

In an exemplary embodiment, the shell 210 is a multipiece housing. For example, the shell 210 includes an upper shell member 216 and a lower shell member 218. The shell 210 includes a cavity 220 between the upper shell member 216 and the lower shell member 218. The shell 210 includes a top wall 222 and a bottom wall 224. The shell 210 includes side walls 226, 228 between the top wall 222 and the bottom wall 224. The upper and lower shell members 216, 218 may meet at a seam along the side walls 226, 228. In an exemplary embodiment, the shell 210 includes a main portion 230 and a nose 232 extending forward from the main portion 230. The nose 232 may be plugged into the module channel 116 of the receptacle cage 110 (shown in FIG. 1).

In an exemplary embodiment, the pluggable module 200 includes a latch 240 coupled to the shell 210. The latch 240 is used to secure the pluggable module 200 to the receptacle cage 110. The latch 240 includes one or more latch fingers 242 configured to be latchably coupled to the receptacle cage 110. In an exemplary embodiment, the latch 240 includes a release element 244 used to release the latch 240 from the receptacle cage 110 to remove the pluggable module 200 from the receptacle cage 110. For example, the release element 244 may include a pull tab or other type of release mechanism.

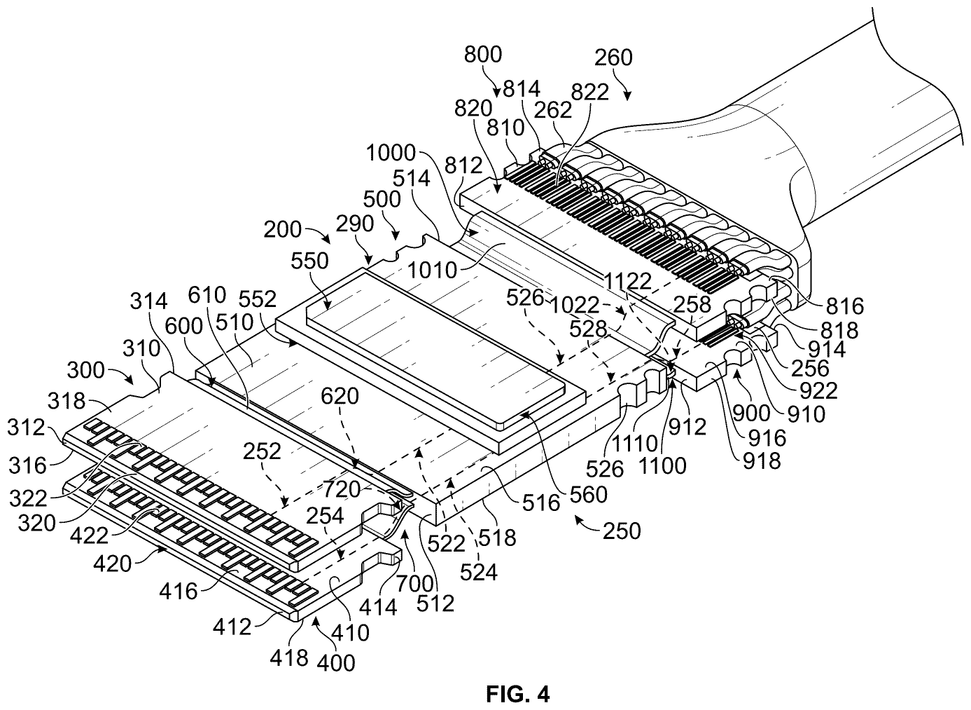

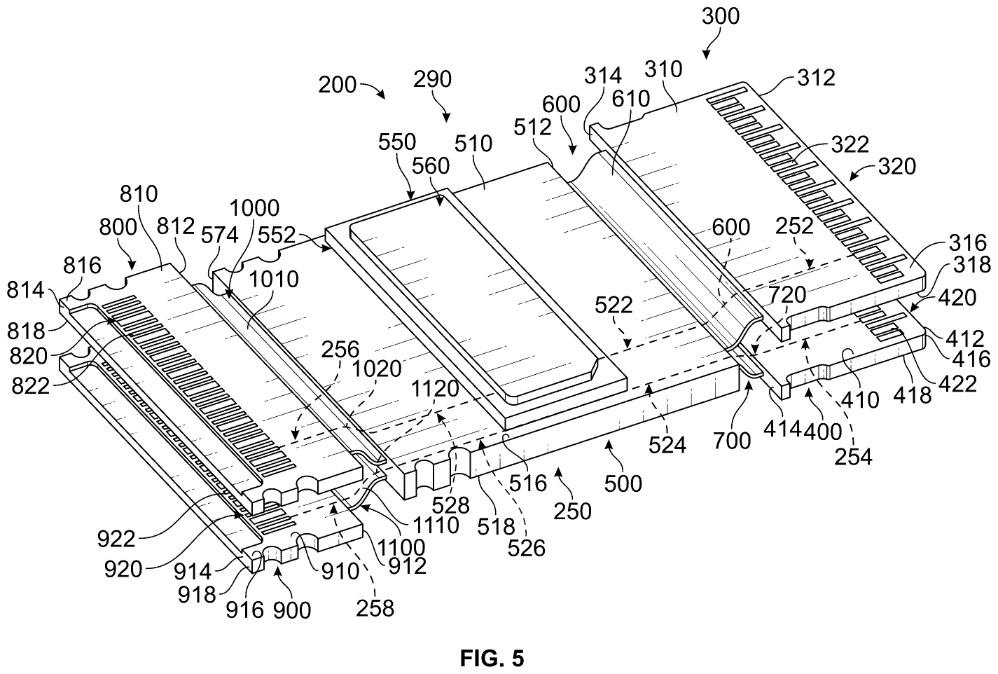

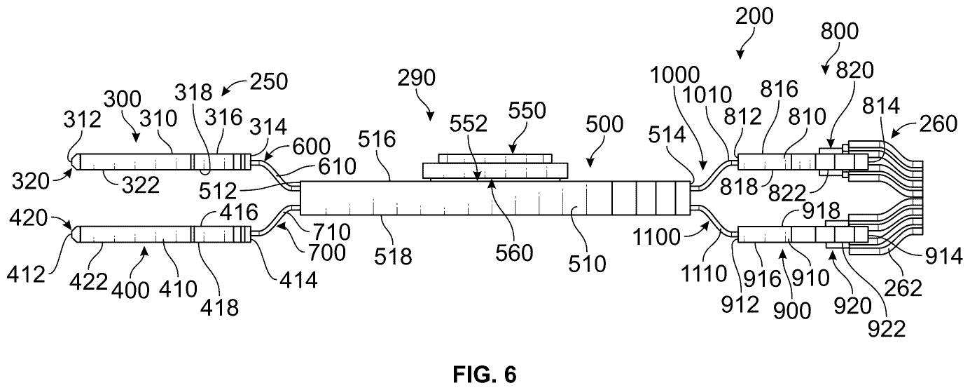

FIG. 4 is a front perspective view of the circuit board assembly 250 in accordance with an exemplary embodiment showing the cable assembly 260 terminated to the circuit board assembly 250. FIG. 5 is a rear perspective view of the circuit board assembly 250 in accordance with an exemplary embodiment. FIG. 6 is a side view of the circuit board assembly 250 in accordance with an exemplary embodiment showing the cable assembly 260 terminated to the circuit board assembly 250. FIGS. 4-6 illustrate an exemplary embodiment of the active module 290 for active signal processing for the signals transmitted through the pluggable module 200. In an exemplary embodiment, the active module 290 includes a main printed circuit board 500 and an active device 550 coupled to the main printed circuit board 500. The active device 550 provides active signaling for the signals or data channels passing through the pluggable module 200. The active device 550 restores or enhances the signals transmitted along the data channels to improve signal conditioning or signal integrity along the data channels to improve communication through the communication system 100.

The cable assembly 260 includes a plurality of cables 262 communicatively coupled to the circuit board assembly 250. In various embodiments, the cables 262 are electrical cables configured to be electrically coupled to the circuit board assembly 250. The cables 262 may be arranged in multiple rows, such as being vertically stacked. For example, the cables 262 may be coupled to different surfaces of different circuit boards of the circuit board assembly 250. In an exemplary embodiment, the cables 262 are twin-axial cables each having a pair of signal conductors arranged in the core of the cable 262. The cables 262 may be shielded cables having cable shields surrounding the pairs of signal conductors. The cables 262 may include drain wires. Other types of cables may be used in alternative embodiments, such as coaxial cables, flat flexible cables, flexible circuits, twisted pair cables, and the like. In an exemplary embodiment, the cables 262 define high speed signal cables configured to transmit high speed data signals, such as 10 Gbps, 25 Gbps, 40 Gbps, 64 Gbps, 100 Gbps, or higher. In alternative embodiments, the cables 262 are fiber optic cables, rather than electrical cables, configured to be optically coupled to optical devices mounted to the circuit board assembly 250.

In an exemplary embodiment, the circuit board assembly 250 includes an upper interface printed circuit board 300, a lower interface printed circuit board 400, the main printed circuit board 500, an upper flexible circuit 600 connected between the upper interface printed circuit board 300 and the main printed circuit board 500, and a lower flexible circuit 700 connected between the lower interface printed circuit board 400 and the main printed circuit board 500. The upper and lower interface printed circuit boards 300, 400 are configured to be mated with the electrical connector assembly 112 (shown in FIG. 2). The circuit board assembly 250 includes first data channels 252 along the upper interface printed circuit board 300 and the upper flexible circuit 600 and a second data channels 254 along the lower interface printed circuit board 400 and the lower flexible circuit 700. The first and second data channels 252, 254 are combined by the active module 290 for active signal processing by the active device 550. For example, the first and second data channels 252, 254 are combined on the main printed circuit board 500 for transmission to/from the active device 550. By combining the first and second data channels 252, 254 on the main printed circuit board 500, the pluggable module 200 may be provided with a single active device 550, rather than a pair of the active devices, which may reduce cost and/or complexity of the circuit board assembly 250. The single active device 550 makes heat transfer or heat dissipation simpler, which improves overall operation or functionality of the pluggable module 200.

In the illustrated embodiment, the circuit board assembly 250 includes an upper cable printed circuit board 800, a lower cable printed circuit board 900, an upper flexible circuit 1000 connected between the upper cable printed circuit board 800 and the main printed circuit board 500, and a lower flexible circuit 1100 connected between the lower cable printed circuit board 900 and the main printed circuit board 500. The circuit board assembly 250 includes third data channels 256 along the upper cable printed circuit board 800 and the upper flexible circuit 1000 and fourth data channels 258 along the lower cable printed circuit board 900 and the lower flexible circuit 1100. The third and fourth data channels 256, 258 are combined at the active module 290 for active signal processing by the active device 550 but split for routing to corresponding cables 262 of the cable assembly 260. The cables 262 are coupled to the upper and lower cable printed circuit boards 800, 900. In alternative embodiments, the cables 262 may be coupled to the main printed circuit board 500, thus eliminating the cable printed circuit boards 800, 900 and the flexible circuits 1000, 1100.

The upper interface printed circuit board 300 includes a rigid substrate 310 extending between a front 312 and a rear 314. The rigid substrate 310 includes an inner surface 316 and an outer surface 318. The inner surface 316 faces the lower interface printed circuit board 400. The upper interface printed circuit board 300 includes an upper mating edge 320 at the front 312. The upper mating edge 320 is configured to be plugged into the first card edge connector 180 (shown in FIG. 2). The upper interface printed circuit board 300 includes upper mating pads 322 proximate to the upper mating edge 320. The upper mating pads 322 are defined by circuits or traces of the upper interface printed circuit board 300. The upper mating pad 322 form portions of the first data channels 252. The upper mating pads 322 are configured to be electrically connected to corresponding circuits or conductors of the upper flexible circuit 600. In an exemplary embodiment, the upper mating pads 322 are provided on both the inner surface 316 and the outer surface 318 to increase the density of the connections at the upper mating edge 320 for mating with the first card edge connector 180. In an exemplary embodiment, the upper mating pads 322 include both signal contacts and ground contacts. For example, the signal contacts may be arranged in pairs and the ground contacts may be located between the pairs of the signal contacts. The ground contacts may be electrically connected to a ground plane of the upper interface printed circuit board 300.

The lower interface printed circuit board 400 includes a rigid substrate 410 extending between a front 412 and a rear 414. The rigid substrate 410 includes an inner surface 416 and an outer surface 418. The inner surface 416 faces the upper interface printed circuit board 300. The lower interface printed circuit board 400 includes a lower mating edge 420 at the front 412. The lower mating edge 420 is configured to be plugged into the second card edge connector 182 (shown in FIG. 2). The lower interface printed circuit board 400 includes lower mating pads 422 proximate to the lower mating edge 420. The lower mating pads 422 are defined by circuits or traces of the lower interface printed circuit board 400. The lower mating pad 422 form portions of the second data channels 254. The lower mating pads 422 are configured to be electrically connected to corresponding circuits or conductors of the lower flexible circuit 700. In an exemplary embodiment, the lower mating pads 422 are provided on both the inner surface 416 and the outer surface 418 to increase the density of the connections at the lower mating edge 420 for mating with the second card edge connector 182. In an exemplary embodiment, the lower mating pads 422 include both signal contacts and ground contacts. For example, the signal contacts may be arranged in pairs and the ground contacts may be located between the pairs of the signal contacts. The ground contacts may be electrically connected to a ground plane of the lower interface printed circuit board 400.

The main printed circuit board 500 includes a rigid substrate 510 extending between a front 512 and a rear 514. The rigid substrate 510 includes an upper surface 516 and a lower surface 518. In the illustrated embodiment, the active device 550 is mounted to the upper surface 516. The active device 550 is mounted to a mounting area 552. In the illustrated embodiment, the mounting area 552 is approximately centered between the front 512 and the rear 514. Other locations are possible in alternative embodiments. In various embodiments, the active device 550 may be soldered to pads or traces at the upper surface 516. In alternative embodiments, the active device 550 may be press-fit into plated vias of the main printed circuit board 500. Other components may be mounted to the main printed circuit board 500, such as such as capacitors, transistors, resistors, memory components, microcontrollers, EEPROM devices, and the like. In various embodiments, the pluggable module 200 may be configured for optical data communication and include an electrical-to-optical converter (not shown) and one or more optical transceivers (not shown) configured to be operably coupled to fiber optic cables.

The main printed circuit board 500 includes a plurality of circuits or conductors to electrically connect the active device 550 to the other portions of the circuit board assembly 250. For example, the main printed circuit board 500 includes first conductors 522 between the upper flexible circuit 600 and the active device 550 and second conductors 524 between the lower flexible circuit 700 and the active device 550. In an exemplary embodiment, the main printed circuit board 500 includes third conductors 526 between the upper flexible circuit 1000 and the active device 550 and forth conductors 528 between the lower flexible circuit 1100 and the active device 550. The conductors 522, 524, 526, 528 may be routed on one or more layers of the main printed circuit board 500 using traces, plated vias, or other circuits of the main printed circuit board 500.

The upper flexible circuit 600 includes a flexible substrate 610 extending between a front and a rear. The flexible substrate 610 includes conductors 620 configured to be electrically connected to the conductors or circuits of the upper interface printed circuit board 300 and the main printed circuit board 500. For example, the conductors 620 are electrically connected to the first conductors 522 of the main printed circuit board 500. The conductors 620 and the first conductors 522 form portions of the first data channels 252. The conductors 620 may include both signal conductors and ground conductors. The signal conductors may be arranged in pairs.

The lower flexible circuit 700 includes a flexible substrate 710 extending between a front and a rear. The flexible substrate 710 includes conductors 720 configured to be electrically connected to the conductors or circuits of the lower interface printed circuit board 400 and the main printed circuit board 500. For example, the conductors 720 are electrically connected to the second conductors 524 of the main printed circuit board 500. The conductors 720 and the second conductors 524 form portions of the second data channels 254. The conductors 720 may include both signal conductors and ground conductors. The signal conductors may be arranged in pairs.

The upper cable printed circuit board 800 includes a rigid substrate 810 extending between a front 812 and a rear 814. The rigid substrate 810 includes an inner surface 816 and an outer surface 818. The inner surface 816 faces the lower cable printed circuit board 900. The upper cable printed circuit board 800 includes an upper termination area 820 at the rear 814. The cables 190 are configured to be terminated to the upper cable printed circuit board 800 at the upper termination area 820. For example, the conductors of the cables 190 may be soldered to upper cable pads 822 at the upper termination area 820. The upper cable pads 822 are defined by circuits or traces of the upper cable printed circuit board 800. The upper cable pads 822 form portions of the third data channels 256. The upper cable pads 822 are configured to be electrically connected to corresponding circuits or conductors of the upper flexible circuit 1000. In an exemplary embodiment, the upper cable pads 822 are provided on both the inner surface 816 and the outer surface 818 to increase the density of the connections at the upper termination area 820 with the cables 190. Additionally or alternatively, the upper cable pads 822 may be provided in multiple rows to increase the number of cables 190 configured to be terminated to the upper cable printed circuit board 800. In an exemplary embodiment, the upper cable pads 822 include both signal contacts and ground contacts. For example, the signal contacts may be arranged in pairs and the ground contacts may be located between the pairs of the signal contacts. Drain wires of the cables 190 may be terminated to the ground contacts. The ground contacts may be electrically connected to a ground plane of the upper cable printed circuit board 800.

The lower cable printed circuit board 900 includes a rigid substrate 910 extending between a front 912 and a rear 914. The rigid substrate 910 includes an inner surface 916 and an outer surface 918. The inner surface 916 faces the upper cable printed circuit board 800. The lower cable printed circuit board 900 includes a lower termination area 920 at the rear 914. The cables 190 are configured to be terminated to the lower cable printed circuit board 900 at the lower termination area 920. For example, the conductors of the cables 190 may be soldered to lower cable pads 922 at the lower termination area 920. The lower cable pads 922 are defined by circuits or traces of the lower cable printed circuit board 900. The lower cable pad 922 form portions of the fourth data channels 258. The lower cable pads 922 are configured to be electrically connected to corresponding circuits or conductors of the lower flexible circuit 1100. In an exemplary embodiment, the lower cable pads 922 are provided on both the inner surface 916 and the outer surface 918 to increase the density of the connections at the lower termination area 920 with the cables 190. Additionally or alternatively, the lower cable pads 922 may be provided in multiple rows to increase the number of cables 190 configured to be terminated to the lower cable printed circuit board 900. In an exemplary embodiment, the lower cable pads 922 include both signal contacts and ground contacts. For example, the signal contacts may be arranged in pairs and the ground contacts may be located between the pairs of the signal contacts. Drain wires of the cables 190 may be terminated to the ground contacts. The ground contacts may be electrically connected to a ground plane of the lower cable printed circuit board 900.

The upper flexible circuit 1000 includes a flexible substrate 1010 extending between a front and a rear. The flexible substrate 1010 includes conductors 1020 configured to be electrically connected to the conductors or circuits of the upper cable printed circuit board 800 and the main printed circuit board 500. For example, the conductors 1020 are electrically connected to the third conductors 526 of the main printed circuit board 500. The conductors 1020 and the third conductors 526 form portions of the third data channels 256. The conductors 1020 may include both signal conductors and ground conductors. The signal conductors may be arranged in pairs.

The lower flexible circuit 1100 includes a flexible substrate 1110 extending between a front and a rear. The flexible substrate 1110 includes conductors 1120 configured to be electrically connected to the conductors or circuits of the lower cable printed circuit board 900 and the main printed circuit board 500. For example, the conductors 1120 are electrically connected to the fourth conductors 528 of the main printed circuit board 500. The conductors 1120 and the fourth conductors 528 form portions of the fourth data channels 258. The conductors 1120 may include both signal conductors and ground conductors. The signal conductors may be arranged in pairs.

In an exemplary embodiment, the active module 290 includes the main printed circuit board 500 and the active device 550 for active signal processing of the signals transmitted along the data channels. The active device 550 is used to meet data budget constraints along the data channels. In an exemplary embodiment, the active device 550 includes one or more repeater devices 560 to restore signals transmitted along the data channels of the circuit board assembly 250. Each repeater device 560 includes an integrated circuit. The repeater device 560 operates as a channel reach extension device to extend the transmission line length along the data channels. For example, when the channel length of the data channel between the various end line components is longer than an allowable channel length, such as per protocol specifications, the repeater device 560 restores the signals by processing the signals along the data channels through the active module 290 such that the distance between the end line components is shorter than the allowable channel length. The repeater device 560 allows reliable, error-free communication for the communication system 100.

The repeater device 560 may be a re-timer device in various embodiments. In various embodiments, the re-timer device may be a re-timer device having sixteen channels. The re-timer device is configured to retransmit a fresh copy of the original signal. The re-timer device may be a mixed signal analog/digital device that is protocol-aware and has the ability to fully recover the data, extract the embedded clock and retransmit a fresh copy of the data using a clean clock. The re-timer device may include a continuous time linear equalizer (CTLE) and a wideband gain stage. The re-timer device may include a clock and data recovery (CDR) circuit, a decision feedback equalizer (DFE) and a transmit (Tx) finite impulse response (FIR) driver. The re-timer device may include a finite state machines (FSMs) and/or a microcontroller to manage the automatic adaptation of the CTLE, wideband gain, DFE and FIR driver, and implement a link training and status state machine (LTSSM). The re-timer device may actively participate in the protocol. The re-timer device may fully recover the data stream and retransmit the data signal on a clean clock to enable extension of the channel to twice the original specification. The DFE of the re-timer device compensates for reflections in the channel response caused by impedance discontinuities in board vias, connectors and package socket-board interfaces along the data transmission line. The re-timer device may examine the received signal and adjust the CTLE and DFE to minimize the bit error rate (BER). The transmitter of the re-timer device may adjust de-emphasis and pre-shoot equalization to minimize BER according to equalization protocol. The re-timer device may have tools for assessing the electrical performance (internal eye monitors, pattern generators, pattern checkers) and protocol performance (link state history monitors, timeout adjustments). The re-timer device may compensate and reset any lane-to-lane skew, effectively doubling the specification budget.

The repeater device 560 may be a re-driver device in various embodiments. The re-driver device is configured to amplify the signal that is transmitted downstream of the re-driver device. The re-driver device may be an analog reach extension device designed to boost the high-frequency portions of the signal, such as to counteract frequency-dependent attenuation along the data channel. The re-driver device may include a continuous time linear equalizer (CTLE), a wideband gain stage and a linear driver. The re-driver device may include receive (RX) side equalizer (EQ) to compensate for frequency-dependent attenuation due to PCB traces or cable conductors along the transmission line. The CTLE may function to open the closed eye of the distorted waveform. The transmit (TX) side of the re-driver device may include a pre-emphasis function (transmit equalizer) to pre-shape the transmit waveform.

In an exemplary embodiment, the main printed circuit board 500 is connected to the upper and lower interface printed circuit boards 300, 400 by the upper and lower flexible circuits 600, 700 to allow the main printed circuit board 500 to move relative to the upper and lower interface printed circuit boards 300, 400. In various embodiments, the main printed circuit board 500 is connected to the upper and lower cable printed circuit boards 800, 900 by the upper and lower flexible circuits 1000, 1100 to allow the main printed circuit board 500 to move relative to the upper and lower cable printed circuit boards 800, 900. The rigid substrate 310 of the upper interface printed circuit board 300 is arranged along a first plane. The rigid substrate 410 of the lower interface printed circuit board 400 is arranged along a second plane. The second plane is oriented generally parallel to and spaced apart from (for example, stacked vertically below) the first plane. The rigid substrate 510 of the main printed circuit board 500 is arranged along a third plane parallel to and spaced apart from (for example, located at a vertical height between) the first and second planes. The rigid substrate 810 of the upper cable printed circuit board 800 is arranged along a fourth plane. The rigid substrate 910 of the lower cable printed circuit board 900 is arranged along a fifth plane. The fifth plane is oriented generally parallel to and spaced apart from (for example, stacked vertically below) the fourth plane. The fourth plane may be generally coplanar with the first plane. The fifth plane may be generally coplanar with the second plane. The third plane is parallel to and spaced apart from (for example, located at a vertical height between) the fourth and fifth planes.

In various embodiments, the circuit board assembly 250 may be manufactured by a rigid-flex fabrication process where portions of the flexible circuit are processed to form the rigid sections. For example, the flexible circuits and the rigid circuits may be manufactured as a single unitary structure with both the rigid and flexible sections. The flexible circuits may be laminated between rigid sections to form the rigid substrates of the rigid circuit boards 300, 400, 500, 800, 900. In an exemplary embodiment, the rigid substrates 310, 410, 810, 910 of the upper and lower interface printed circuit boards 300, 400 and the upper and lower cable printed circuit boards 800, 900 are single thickness boards. However, the circuits of such boards are combined at the main printed circuit board 500, which may be a double thickness board.

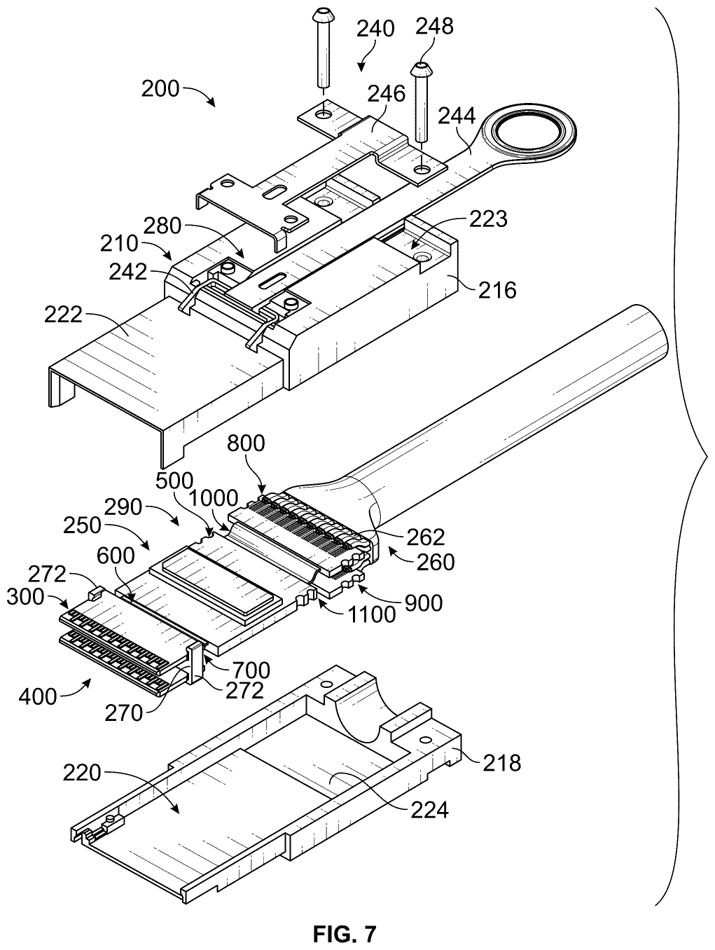

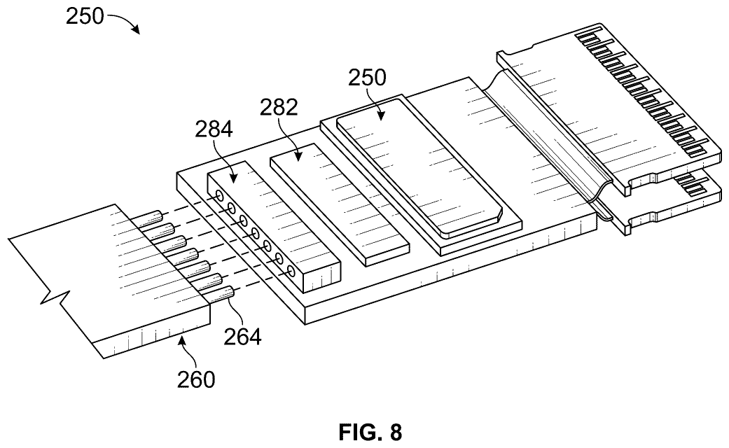

FIG. 7 is an exploded view of the pluggable module 200 in accordance with an exemplary embodiment. The pluggable module 200 includes the shell 210, the latch 240, the circuit board assembly 250, and the cable assembly 260. In an exemplary embodiment, the circuit board assembly 250 is a dual paddle card assembly having a pair of stacked interface circuit boards 300, 400 configured to be mated with the electrical connector assembly 112 (shown in FIG. 2) both electrically connected to the active module 290 by the corresponding flexible circuits 600, 700. A pair of stacked cable circuit boards 800, 900 are electrically connected to the active module 290 by the corresponding flexible circuits 1000, 1100.

The shell 210 includes the upper shell member 216 and the lower shell member 218, which are coupled together to form the cavity 220. The circuit board assembly 250 and the cable assembly 260 are received in the cavity 220 between the upper and lower shell members 216, 218. In an exemplary embodiment, the flexible circuits 1000, 1100 allow variable positioning of the cable circuit boards 800, 900 in the cavity 220 for easy termination and connection to the cables 262. The flexible circuits 1000, 1100 allow variable positioning of the main printed circuit board 500 in the cavity 220 relative to the cable circuit boards 800, 900.

In an exemplary embodiment, the circuit board assembly 250 includes a circuit board spacer 270 used to hold relative positions of the upper and lower interface circuit boards 300, 400, such as to vertically position the interface circuit boards 300, 400 at a predetermined spacing for plugging into the card edge connectors 180, 182 (shown in FIG. 2). The circuit board spacer 270 may include locating features 272 for locating the circuit board spacer 270, and thus the interface circuit boards 300, 400, relative to the shell 210. For example, the circuit board spacer 270 may engage the top wall 222 and/or the bottom wall 224 of the shell 210.

In an exemplary embodiment, the flexible circuits 600, 700 allow variable positioning of the main printed circuit board 500 in the cavity 220 relative to the interface circuit boards 300, 400. In an exemplary embodiment, the pluggable module 200 may include a heat transfer device 280. In an exemplary embodiment, the active device 550 is configured to be thermally coupled to the heat transfer device 280 to transfer heat from the active device 550 for cooling the active device 550. The heat transfer device 280 may be defined by the top wall 222. Alternatively, the heat transfer device 280 may be a separate component, such as a heat sink, coupled to the shell 210, such as to the top wall 222. In an exemplary embodiment, the active device 550 is configured to physically engage the heat transfer device 280. For example, the top surface of the active device 550 may engage the interior surface of the top wall 222. Optionally, thermal interface material, such as thermal grease, may be provided at the interface between the active device 550 and the heat transfer device 280. In an exemplary embodiment, the main printed circuit board 500 is movable within the cavity 220 (for example, movement allowed by the flexible circuits 600, 700) to allow positioning of the active device 550 relative to the heat transfer device 280. In various embodiments, a biasing element (not shown) such as a spring, may be positioned below the main printed circuit board 500 to upward bias the main printed circuit board 500 and the active device 550 into thermal engagement with the heat transfer device 280.

The latch 240 is coupled to the top wall 222 of the shell 210. For example, the latch 240 is received in a latch pocket 223 forming in the top wall 222. The latch 240 is used to secure the pluggable module 200 to the receptacle cage 110. The latch 240 includes the latch fingers 242 and the release element 244 operably coupled to the latch fingers 242 to rotate or release the latch fingers 242. In an exemplary embodiment, the latch 240 includes a cover 246 used to cover the release element 244 and/or the latch fingers 242. The cover 246 may be secured using fasteners 248. The fasteners 248 may be used to secure the upper shell member 216 and the lower shell member 218.

FIG. 8 is a front perspective view of the circuit board assembly 250 in accordance with an exemplary embodiment showing the cable assembly 260 as a fiber optic cable assembly. In the illustrated embodiment, the circuit board assembly 250 includes an electrical-to-optical converter 282 and an optical transceiver 284 configured to be operably coupled to a fiber optic cable 264 of the cable assembly 260. The electrical-to-optical converter 282 and the optical transceiver 284 are mounted to the main printed circuit board 500. The active device 550 processes the signals transmitted to/from the electrical-to-optical converter 282 and the optical transceiver 284. The electrical-to-optical converter 282 and the optical transceiver 284 are movable with the main printed circuit board 500. The electrical-to-optical converter 282 and/or the optical transceiver 284 may be thermally coupled to the heat transfer device 280 (shown in FIG. 7) to dissipate heat from the electrical-to-optical converter 282 and/or the optical transceiver 284.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112 (f), unless and until such claim limitations expressly use the phrase “means for” followed by a statement of function void of further structure.

What is claimed is:

1. A circuit board assembly for a pluggable module comprising:
an upper interface printed circuit board including first data channels, the upper interface printed circuit board including an upper mating edge and upper mating pads proximate to the upper mating edge forming portions of the first data channels, the upper mating edge configured to be plugged into a first card edge connector to mate the upper mating pads with first contacts of the first card edge connector;
a lower interface printed circuit board including second data channels, the lower interface printed circuit board including a lower mating edge and lower mating pads proximate to the lower mating edge forming portions of the second data channels, the lower mating edge configured to be plugged into a second card edge connector to mate the lower mating pads with second contacts of the second card edge connector;
a main printed circuit board including an active device configured to be electrically connected to the first data channels and the second data channels, the active device including a repeater device restoring signals transmitting along the first data channels and the second data channels;
an upper flexible circuit connected between the upper interface printed circuit board and the main printed circuit board to electrically connect the first data channels to the active device; and
a lower flexible circuit connected between the lower interface printed circuit board and the main printed circuit board to electrically connect the second data channels to the active device.

2. The circuit board assembly of claim 1, wherein the upper interface printed circuit board and the lower interface printed circuit board form a dual paddle card interface for the pluggable module.

3. The circuit board assembly of claim 1, wherein the upper and lower flexible circuits allow the main printed circuit board to move relative to the upper and lower interface and circuit boards.

4. The circuit board assembly of claim 1, wherein the first and second data channels from the upper and lower interface printed circuit boards are combined on the main printed circuit board for processing by the active device.

5. The circuit board assembly of claim 1, wherein the upper interface printed circuit board includes a rigid substrate, the lower interface printed circuit board including a rigid substrate, the main printed circuit board including a rigid substrate, the upper and lower flexible circuits extending between the corresponding rigid substrates.

6. The circuit board assembly of claim 5, wherein the rigid substrate of the upper interface printed circuit board is arranged along a first plane, the rigid substrate of the lower interface printed circuit board being arranged along a second plane parallel to and spaced apart from the first plane, the rigid substrate of the main printed circuit board being arranged along a third plane parallel to and spaced apart from the first and second planes.

7. The circuit board assembly of claim 1, wherein the upper interface printed circuit board includes an inner surface and an outer surface, the upper mating pads being arranged on both the inner surface and the outer surface of the upper interface printed circuit board, the lower interface printed circuit board including an inner surface and an outer surface, the lower mating pads being arranged on both the inner surface and the outer surface of the lower interface printed circuit board.

8. The circuit board assembly of claim 1, further comprising:
an upper cable printed circuit board including an upper cable terminating area and upper cable pads at the upper cable terminating area configured to be terminated to conductors of cables;
a lower cable printed circuit board including a lower cable terminating area and lower cable pads at the lower cable terminating area configured to be terminated to conductors of cables; and
flexible circuits between the main printed circuit board and the upper and lower cable printed circuit boards to electrically connect the upper and lower cable pads to the active device.

9. The circuit board assembly of claim 8, wherein the upper cable printed circuit board includes an inner surface and an outer surface, the upper cable pads being arranged on both the inner surface and the outer surface of the upper cable printed circuit board, the lower cable printed circuit board including an inner surface and an outer surface, the lower cable pads being arranged on both the inner surface and the outer surface of the lower cable printed circuit board.

10. The circuit board assembly of claim 1, wherein the repeater device is one of a re-timer device or a re-driver device for processing the first and second data channels.

11. The circuit board assembly of claim 1, wherein the main printed circuit board includes an electrical-to-optical converter and an optical transceiver configured to be operably coupled to a fiber optic cable.

12. A pluggable module comprising:
a shell having a cavity, the shell having a mating end, the shell having an opening at the mating end; and
a circuit board assembly received in the cavity of the shell, the circuit board assembly including an upper interface printed circuit board, a lower interface printed circuit board, an main printed circuit board, an upper flexible circuit connected between the upper interface printed circuit board and the main printed circuit board, and a lower flexible circuit connected between the lower interface printed circuit board and the main printed circuit board;
the upper interface printed circuit board including first data channels, the upper flexible circuit electrically connecting the first data channels to the active device, the upper interface printed circuit board including an upper mating edge and upper mating pads proximate to the upper mating edge forming portions of the first data channels, the upper mating edge presented at the mating end of the shell for plugging into a first card edge connector to mate the upper mating pads with first contacts of the first card edge connector;
the lower interface printed circuit board including second data channels, the lower flexible circuit electrically connecting the second data channels to the active device, the lower interface printed circuit board including a lower mating edge and lower mating pads proximate to the lower mating edge forming portions of the second data channels, the lower mating edge presented at the mating end of the shell for plugging into a second card edge connector to mate the lower mating pads with second contacts of the second card edge connector;
the main printed circuit board including an active device electrically connected to the first data channels and the second data channels, the active device including a repeater device restoring signals transmitting along the first data channels and the second data channels.

13. The pluggable module of claim 12, wherein the upper and lower flexible circuits allow the main printed circuit board to move in the cavity relative to the shell.

14. The pluggable module of claim 12, wherein the first and second data channels from the upper and lower interface printed circuit boards are combined on the main printed circuit board for processing by the active device.

15. The pluggable module of claim 12, wherein the upper interface printed circuit board includes a rigid substrate, the lower interface printed circuit board including a rigid substrate, the main printed circuit board including a rigid substrate, the upper and lower flexible circuits extending between the corresponding rigid substrates.

16. The pluggable module of claim 12, further comprising:
an upper cable printed circuit board including an upper cable terminating area and upper cable pads at the upper cable terminating area configured to be terminated to conductors of cables;
a lower cable printed circuit board including a lower cable terminating area and lower cable pads at the lower cable terminating area configured to be terminated to conductors of cables; and
flexible circuits between the main printed circuit board and the upper and lower cable printed circuit boards to electrically connect the upper and lower cable pads to the active device.

17. A pluggable module comprising:
a shell having a cavity, the shell having a mating end and a cable end, the shell having an opening at the mating end;
a cable assembly extending from the cable end, the cable assembly cables having conductors; and
a circuit board assembly received in the cavity of the shell and terminated to the conductors of the cables of the cable assembly, the circuit board assembly including an upper interface printed circuit board, a lower interface printed circuit board, a main printed circuit board, an upper flexible circuit connected between the upper interface printed circuit board and the main printed circuit board, and a lower flexible circuit connected between the lower interface printed circuit board and the main printed circuit board;
the upper interface printed circuit board including first data channels, the upper flexible circuit electrically connecting the first data channels to the active device, the upper interface printed circuit board including an upper mating edge and upper mating pads proximate to the upper mating edge forming portions of the first data channels, the upper mating edge presented at the mating end of the shell for plugging into a first card edge connector to mate the upper mating pads with first contacts of the first card edge connector;
the lower interface printed circuit board including second data channels, the lower flexible circuit electrically connecting the second data channels to the active device, the lower interface printed circuit board including a lower mating edge and lower mating pads proximate to the lower mating edge forming portions of the second data channels, the lower mating edge presented at the mating end of the shell for plugging into a second card edge connector to mate the lower mating pads with second contacts of the second card edge connector;
the main printed circuit board including an active device configured to be electrically connected to the first data channels and the second data channels and configured to be electrically connected to the conductors of the cables of the cable assembly, the active device including a repeater device restoring signals transmitting along the first data channels and the second data channels.

18. The pluggable module of claim 17, wherein the upper and lower flexible circuits allow the main printed circuit board to move in the cavity relative to the shell.

19. The pluggable module of claim 17, wherein the first and second data channels from the upper and lower interface printed circuit boards are combined on the main printed circuit board for processing by the active device.

20. The pluggable module of claim 17, further comprising:
an upper cable printed circuit board including an upper cable terminating area and upper cable pads at the upper cable terminating area terminated to corresponding conductors of the cables;
a lower cable printed circuit board including a lower cable terminating area and lower cable pads at the lower cable terminating area configured to be terminated to corresponding conductors of the cables; and
flexible circuits between the main printed circuit board and the upper and lower cable printed circuit boards to electrically connect the upper and lower cable pads to the active device.
